(19) United States
(12) Patent Application Publication
(10) Pub. No.: US 2025/0255075 A1
(43) Pub. Date: Aug. 7, 2025

(54) DISPLAY DEVICE

(71) Applicant: LG Display Co., Ltd., Seoul (KR)

(72) Inventors: Soojin KIM, Incheon (KR); HEUMEIL BAEK, Seoul (KR); DAE-IL KANG, Gimpo-si (KR); Sungmoo KIM, Goyang-si (KR)

(73) Assignee: LG Display Co., Ltd., Seoul (KR)

(21) Appl. No.: 18/967,266

(22) Filed: Dec. 3, 2024

(30) Foreign Application Priority Data
Feb. 1, 2024 (KR) 10-2024-0015686

(51) Int. Cl. H10H 29/80; H01L 25/075; H10H 29/85; H10H 29/855

(52) U.S. Cl. CPC H10H 29/8325; H01L 25/0753; H10H 29/8323; H10H 29/8552; H10H 29/857; H10H 29/942

(57) ABSTRACT

A display device can include a substrate having a plurality of first sub pixels and a plurality of second sub pixels, a plurality of first light emitting diodes disposed in the plurality of first sub pixels and configured to emit light to one surface of the substrate, and a plurality of second light emitting diodes disposed in the plurality of second sub pixels and configured to emit light to an opposite surface to one surface of the substrate. The plurality of first light emitting diodes and the plurality of second light emitting diodes are alternately disposed on the plane. Accordingly, light is emitted to opposite surfaces of the substrate to display images on the opposite surfaces of the substrate.

### CROSS-REFERENCE TO RELATED APPLICATIONS

This application claims priority to Korean Patent Application No. 10-2024-0015686 filed on Feb. 1, 2024, in the Korean Intellectual Property Office, the entire disclosure of which is hereby expressly incorporated by reference into the present application.

### BACKGROUND

### Field

The present disclosure relates to a display device, and more particularly, to a dual emission display device using a light emitting diode (LED).

### Discussion of the Related Art

Among display devices which are used for a monitor of a computer, a television, or a cellular phone, there are an organic light emitting display device (OLED) which is a self-emitting device, a liquid crystal display device (LCD) which requires a separate light source, and the like.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device in which images are displayed on both surfaces of the display device.

Another object to be achieved by the present disclosure is to provide a dual emission type display device in which images are displayed on both surfaces of the substrate of the display device.

Still another object to be achieved by the present disclosure is to provide a display device in which light interference of a top emission light emitting diode and a bottom emission light emitting diode is reduced.

Still another object to be achieved by the present disclosure is to provide a display device in which a crosstalk due to light interference of a top emission light emitting diode and a bottom emission light emitting diode is reduced.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a plurality of first sub pixels and a plurality of second sub pixels; a plurality of first light emitting diodes which is disposed in the plurality of first sub pixels and emits light to one surface of the substrate; and a plurality of second light emitting diodes which is disposed in the plurality of second sub pixels and emits light to an opposite surface to one surface of the substrate, and the plurality of first light emitting diodes and the plurality of second light emitting diodes are alternately disposed on the plane. Accordingly, light is emitted to one surface and an opposite surface to that one surface of the substrate to display images on both opposite surfaces of the substrate.

Other detailed matters of the example embodiments are included in the detailed description and the drawings.

According to a further aspect of the present disclosure, light is emitted to a top and a bottom of the substrate to display images on both or multiple surfaces of the substrate.

According to a further aspect of the present disclosure, a dual emission display device in which images are displayed on both surfaces of the display device can be provided.

According to a further aspect of the present disclosure, a top emission light emitting diode and a bottom emission light emitting diode are alternately disposed to minimize the interference of light of the top emission light emitting diode and light of the bottom emission light emitting diode.

According to a further aspect of the present disclosure, a black matrix which encloses each of a top emission light emitting diode and a bottom emission light emitting diode is formed to minimize the interference of light of the top emission light emitting diode and light of the bottom emission light emitting diode.

According to a further aspect of the present disclosure, a top emission light emitting diode and a bottom emission light emitting diode are disposed in different areas to suppress the interference of light of the top emission light emitting diode and light of the bottom emission light emitting diode and minimize the crosstalk.

The effects according to the present disclosure are not limited to the contents exemplified above, and more various effects are included in the present disclosure.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a schematic diagram of a display device according to an example embodiment of the present disclosure;

FIG. 2A is a partial cross-sectional view of a display device according to an example embodiment of the present disclosure;

FIG. 2B is a perspective view of a tiling display device according to an example embodiment of the present disclosure;

FIG. 3 is an enlarged plan view of an active area of a display device according to an example embodiment of the present disclosure;

FIG. 4 is a cross-sectional view of a sub pixel of a display device according to an example embodiment of the present disclosure; and

FIG. 5 is a cross-sectional view of a sub pixel of a display device according to another example embodiment of the present disclosure.

### DETAILED DESCRIPTION OF THE EMBODIMENTS

Advantages and characteristics of the present disclosure and a method of achieving the advantages and characteristics will be clear by referring to various embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise. Further, the term “can” fully encompasses all the meanings and coverages of the term “may.”

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or layer or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

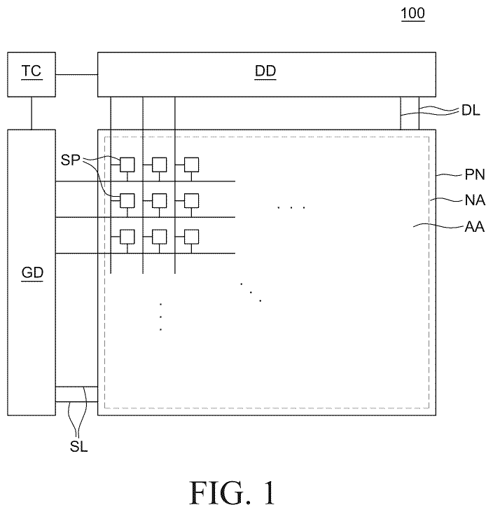

FIG. 1 is a schematic diagram of a display device according to an example embodiment of the present disclosure. In FIG. 1, for the convenience of description, among various components of a display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD can convert the image data into a data voltage using a reference gamma voltage and supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP can be formed at intersections of the scan lines SL and the data lines DL.

In the display panel PN, an active area (or display area) AA and a non-active area (or non-display area) NA can be defined.

The active area AA is an area in which images are displayed in the display device 100. In the active area AA, a plurality of sub pixels SP which configures a plurality of pixels PX and a pixel circuit for driving the plurality of sub pixels SP can be disposed. The plurality of sub pixels SP is a minimum unit which configures the active area AA and n sub pixels SP can form one pixel PX. In each of the plurality of sub pixels SP, a light emitting diode and a thin film transistor for driving the light emitting diode can be disposed. The light emitting diode can be defined in different manners depending on the type of the display panel PN. For example, when the display panel PN is an inorganic light emitting display panel PN, the light emitting diode can be a light emitting diode (LED) or a micro light emitting diode (micro LED).

In the active area AA, a plurality of signal lines which transmit various signals to the plurality of sub pixels SP are disposed. For example, the plurality of signal lines can include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, or a driving integrated circuit (IC), such as a gate driver IC or a data driver IC, can be disposed.

In the meantime, the non-active area NA can be located on a rear surface of the display panel PN, for example, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN can be electrically connected to the data driver DD and the timing controller TC by bonding the flexible film and the printed circuit board to the pad electrode formed in the non-active area NA of the display panel PN.

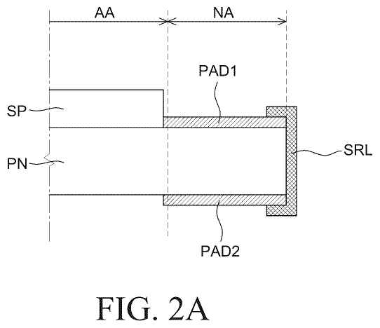

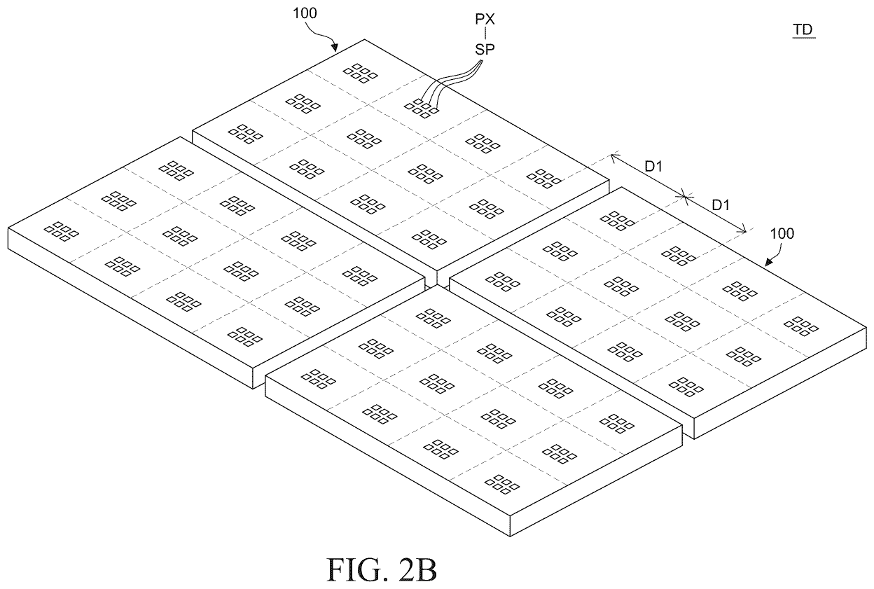

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA on the front surface of the display panel PN can be minimized. Therefore, when the gate driver GD, the data driver DD, and the timing controller TC are connected to the display panel PN as described above, a zero bezel in which there is no bezel can be substantially implemented, which will be described in more detail with reference to FIGS. 2A and 2B.

FIG. 2A is a partial cross-sectional view of a display device according to an example embodiment of the present disclosure. FIG. 2B is a perspective view of a tiling display device according to an example embodiment of the present disclosure.

In the non-active area NA of the display panel PN, a plurality of pad electrodes for transmitting various signals to the plurality of sub pixels SP are disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, various signal lines connected to the plurality of sub pixels SP, for example, a scan line SL or a data line DL extends from the active area AA to the non-active area NA to be electrically connected to the first pad electrode PAD1.

A side line SRL is disposed along a side surface of the display panel PN. The side line SRL can electrically connect the first pad electrode PAD1 on the front surface of the display panel PN and the second pad electrode PAD2 on the rear surface of the display panel PN. Therefore, a signal from a driving component on the rear surface of the display panel PN can be transmitted to the plurality of sub pixels SP through the second pad electrode PAD2, the side line SRL, and the first pad electrode PAD1. Accordingly, a signal transmitting path is formed from the front surface of the display panel PN to the side surface and the rear surface to minimize an area of the non-active area NA on the front surface of the display panel PN.

Referring to FIG. 2B, a tiling display device TD having a large screen size can be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality can be improved.

For example, the plurality of sub pixels SP can form one pixel PX and a distance D1 between an outermost pixel PX of one display device 100 and an outermost pixel PX of another display device 100 adjacent to the one display device can be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the example embodiment of the present disclosure can be a general display device with a bezel, but is not limited thereto.

Hereinafter, a display panel PN of a display device 100 according to an example embodiment of the present disclosure will be described in more detail.

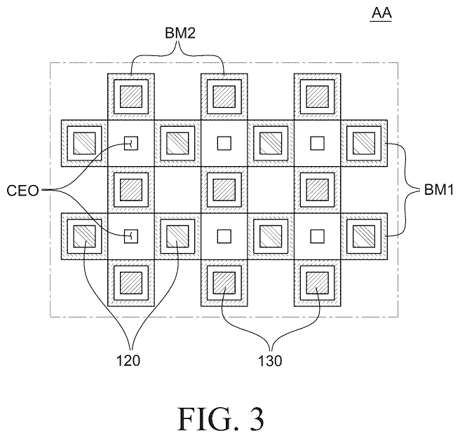

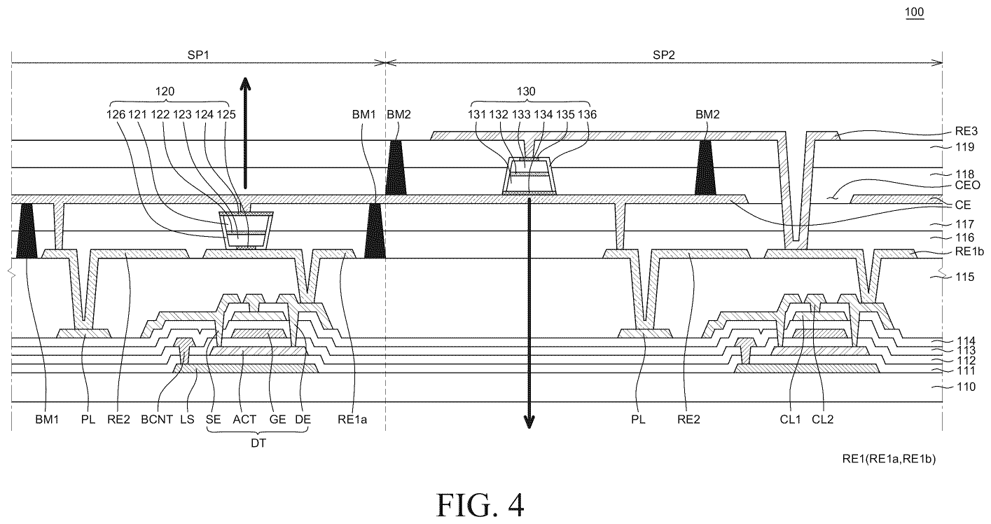

FIG. 3 is an enlarged plan view of an active area of a display device according to an example embodiment of the present disclosure. FIG. 4 is a cross-sectional view of a sub pixel of a display device according to an example embodiment of the present disclosure.

Referring to FIGS. 3 and 4, the display device 100 according to the example embodiment of the present disclosure can be a dual emission display device 100. For example, the display device 100 according to the example embodiment of the present disclosure can be a dual emission display device 100 in which images are displayed on both surfaces of the display device 100. The image can be displayed on a top surface of the substrate 110 and the image can be displayed on a bottom surface of the substrate 110, simultaneously. Images displayed on both surfaces of the display device 100 can be the same image or different images.

The plurality of sub pixels SP of the display device 100 include a plurality of first sub pixels SP1 and a plurality of second sub pixels SP2. In the plurality of first sub pixels SP1 and the plurality of second sub pixels SP2, images can be displayed on different surfaces of the substrate 110. For example, in the plurality of first sub pixels SP1, the image is displayed on the front surface of the substrate 110 and in the plurality of second sub pixels SP2, the image is displayed on the rear surface of the substrate 110.

The plurality of first sub pixels SP1 include a plurality of first light emitting diodes 120 and the plurality of second sub pixels SP2 include a plurality of second light emitting diodes 130. Light emitted from the first light emitting diode 120 of the plurality of first sub pixels SP1 can be emitted to one surface of the substrate 110 and light emitted from the second light emitting diode 130 of the plurality of second sub pixels SP2 can be emitted to an opposite surface of the one surface of the substrate 110. For example, light emitted from the first light emitting diode 120 of the plurality of first sub pixels SP1 can be directed to the top of the substrate 110 and light emitted from the second light emitting diode 130 of the plurality of second sub pixels SP2 can be directed to the bottom of the substrate 110. In this case, the first light emitting diode 120 for displaying an image on the front surface of the substrate 110 can also be referred to as the top emission light emitting diode and the second light emitting diode 130 for displaying an image on the rear surface of the substrate 110 can also be referred to as the bottom emission light emitting diode.

At this time, the plurality of first light emitting diodes 120 of the plurality of first sub pixels SP1 and the plurality of second light emitting diodes 130 of the plurality of second sub pixels SP2 can be alternately disposed. The plurality of first light emitting diodes 120 and the plurality of second light emitting diodes 130 may not overlap each other. The plurality of first light emitting diodes 120 and the plurality of second light emitting diodes 130 can be disposed in different rows and different columns. For example, the plurality of first light emitting diodes 120 of the plurality of first sub pixels SP1 can be disposed to form a plurality of rows and a plurality of columns and the plurality of second light emitting diodes 130 of the plurality of second sub pixels SP2 can be disposed to form a plurality of rows and a plurality of columns. At this time, the plurality of first light emitting diodes 120 and the plurality of second light emitting diodes 130 can be disposed in different rows. The plurality of first light emitting diodes 120 and the plurality of second light emitting diodes 130 can be disposed in different columns. Accordingly, the plurality of first light emitting diodes 120 of the plurality of first sub pixels SP1 and the plurality of second light emitting diodes 130 of the plurality of second sub pixels SP2 can be alternately disposed in the row direction and the column direction in a plan view.

The plurality of first light emitting diodes 120 of the plurality of first sub pixels SP1 and the plurality of second light emitting diodes 130 of the plurality of second sub pixels SP2 are alternately disposed so that light emitted from the sub pixels SP may not interfere with each other. If the first light emitting diode 120 and the second light emitting diode 130 are disposed to overlap each other, light emitted from the first light emitting diode 120 of the first sub pixel SP1 and light emitted from the second light emitting diode 130 of the second sub pixel SP2 interfere with each other to cause a crosstalk. A part of light emitted from the first light emitting diode 120 and a part of light emitted from the second light emitting diode 130 travel toward the top and the bottom of the substrate 110 so that a display quality can be degraded. The first light emitting diode 120 and the second light emitting diode 130 can be alternately disposed so that the first light emitting diode 120 and the second light emitting diode 130 do not overlap. Therefore, light emitted from the first light emitting diode 120 of the first sub pixel SP1 and light emitted from the second light emitting diode 130 of the second sub pixel SP2 can be separated so as not to interfere with each other.

In this case, a black matrix BM1 and BM2 is disposed between the plurality of first sub pixels SP1 and the plurality of second sub pixels SP2 to shield the light emitted from each sub pixel SP to suppress color mixture and interference. The black matrix BM1 and BM2 includes a first black matrix BM1 disposed in the first sub pixel SP1 so as to enclose the first light emitting diode 120 and a second black matrix BM2 disposed in the second sub pixel SP2 so as to enclose the second light emitting diode 130. The first black matrix BM1 can guide the light emitted from the first light emitting diode 120 of the first sub pixel SP1 to be emitted only to an area corresponding to the first sub pixel SP1. The second black matrix BM2 can guide the light emitted from the second light emitting diode 130 of the second sub pixel SP2 to be emitted only to an area corresponding to the second sub pixel SP2. Light emitted from the first light emitting diode 120 can be suppressed from being directed to the adjacent second sub pixel SP2 by the first black matrix BM1 and the second black matrix BM2. Light emitted from the second light emitting diode 130 can also be suppressed from being directed to the adjacent first sub pixel SP1 by the first black matrix BM1 and the second black matrix BM2.

Referring to FIG. 4, the substrate 110 is a component for supporting various components included in the display device 100 and can be formed of an insulating material. For example, the substrate 110 can be formed of glass or resin. Further, the substrate 110 can be configured to include a polymer or plastics or can be formed of a material having flexibility.

A light shielding layer LS is disposed in each of the plurality of sub pixels SP on the substrate 110. The light shielding layer LS blocks light incident onto an active layer ACT of the driving transistor DT from the bottom of the substrate 110. Light which is incident onto the active layer ACT of the driving transistor DT is blocked by the light shielding layer LS to reduce a leakage current.

A buffer layer 111 is disposed on the substrate 110 and the light shielding layer LS. The buffer layer 111 can reduce permeation of moisture or impurities through the substrate 110. For example, the buffer layer 111 can be configured by a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

A driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT can be formed of a semiconductor material, such as an oxide semiconductor, amorphous silicon, or polysilicon, but is not limited thereto.

A gate insulating layer 112 is disposed on the active layer ACT. The gate insulating layer 112 is an insulating layer which insulates the active layer ACT from the gate electrode GE and can be configured by a single layer or a double layer of silicon oxide (SiOx) or silicon nitride (SiNx), but is not limited thereto.

The gate electrode GE is disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, a contact hole through which each of the source electrode SE and the drain electrode DE is connected to the active layer ACT is formed. The first interlayer insulating layer 113 and the second interlayer insulating layer 114 are insulating layers for protecting a component below the first interlayer insulating layer 113 and the second interlayer insulating layer 114 and can be configured by a single layer or a double layer of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, for example, a plurality of insulating layers is disposed between the gate electrode GE, and the source electrode SE and the drain electrode DE. However, only one insulating layer can be disposed between the gate electrode GE, and the source electrode SE and the drain electrode DE.

When a plurality of insulating layers, such as the first interlayer insulating layer 113 and the second interlayer insulating layer 114, is disposed between the gate electrode GE, and the source electrode SE and the drain electrode DE, an electrode can be additionally formed between the first interlayer insulating layer 113 and the second interlayer insulating layer 114. The additionally formed electrode can form a capacitor with the other configuration disposed below the first interlayer insulating layer 113 or above the second interlayer insulating layer 114.

For example, a first conductive layer CL1 can be disposed between the first interlayer insulating layer 113 and the second interlayer insulating layer 114 and a second conductive layer CL2 which is electrically connected to the first conductive layer CL1 can be disposed on the second interlayer insulating layer 114. The first conductive layer CL1 and the second conductive layer CL2 are disposed so as to overlap a gate electrode GE of a driving transistor DT to form a capacitor with the gate electrode GE of the driving transistor DT. Accordingly, various conductive layers, such as the first conductive layer CL1 and the second conductive layer CL2, are disposed on the substrate 110 to form a capacitor.

Next, an auxiliary electrode BCNT is disposed on the gate insulating layer 112. The auxiliary electrode BCNT is an electrode for applying a voltage to the light shielding layer LS below the buffer layer 111. For example, the light shielding layer LS is electrically connected to another configuration disposed on the substrate 110 by means of the auxiliary electrode BCNT to be applied with a voltage. The light shielding layer LS which is applied with a voltage by means of the auxiliary electrode BCNT does not operate as a floating gate and can minimize a fluctuation of a threshold voltage of the driving transistor DT which is generated by the floated light shielding layer LS.

A power line PL is disposed on the second interlayer insulating layer 114. The power line PL is electrically connected to the light emitting diode together with the driving transistor DT to allow the light emitting diode to emit light. The power line PL can be configured by a conductive material such as copper (Cu), aluminum (Al), molybdenum (Mo), nickel (Ni), titanium (Ti), chrome (Cr), or an alloy thereof, but is not limited thereto.

The organic insulating layer 115 is disposed on the driving transistor DT and the power line PL. The organic insulating layer 115 can planarize an upper portion of the substrate 110 on which the driving transistor DT is disposed. The organic insulating layer 115 can be configured by a single layer or a double layer, and for example, can be formed of photoresist or an acrylic organic material, but is not limited thereto.

A plurality of first reflective electrodes RE1 and a plurality of second reflective electrodes RE2 which are spaced apart from each other can be disposed on the organic insulating layer 115. The plurality of first reflective electrodes RE1 can electrically connect the plurality of light emitting diodes 120 and 130 to the driving transistor DT. The plurality of second reflective electrodes RE2 can electrically connect the plurality of light emitting diodes 120 and 130 to the power line PL. Further, the plurality of first reflective electrodes RE1 and the plurality of second reflective electrodes RE2 can serve as a reflective plate which reflects light emitted from the plurality of light emitting diodes 120 and 130 toward the top of the substrate 110 or the bottom of the substrate 110. The plurality of first reflective electrodes RE1 and the plurality of second reflective electrodes RE2 are formed of a conductive material having an excellent reflective property to reflect light emitted from a first light emitting diode 120, among the plurality of light emitting diodes 120 and 130, toward the top of the first light emitting diode 120. For example, the plurality of first reflective electrodes RE1 and the plurality of second reflective electrodes RE2 can be formed of a metal material having an excellent reflective property, such as aluminum (Al), silver (Ag), copper (Cu), palladium (Pd), or an alloy thereof, but are not limited thereto.

The plurality of first reflective electrodes RE1 can electrically connect each of the first light emitting diode 120 and the second light emitting diode 130 to the driving transistor DT. The plurality of first reflective electrodes RE1 can be connected to the source electrode SE or the drain electrode DE of the driving transistor DT through a contact hole formed in the organic insulating layer 115. The first reflective electrode RE1 can be electrically connected to a first p-type electrode 125 of the first light emitting diode 120 and a second p-type electrode 135 of the second light emitting diode 130.

The plurality of first reflective electrodes RE1 include a plurality of 1-1-th reflective electrodes RE1a and a plurality of 1-2-th reflective electrodes RE1b. Among the plurality of sub pixels SP, in a first sub pixel SP1, the 1-1-th reflective electrode RE1a can be disposed and in a second sub pixel SP2, the 1-2-th reflective electrode RE1b can be disposed. The plurality of 1-1-th reflective electrodes RE1a are electrodes which electrically connect the plurality of first light emitting diodes 120 and the driving transistor DT in the first sub pixel SP1. Further, the plurality of 1-2-th reflective electrodes RE1b are electrodes which electrically connect the plurality of second light emitting diodes 130 and the driving transistor DT in the second sub pixel SP2.

The plurality of second reflective electrodes RE2 can electrically connect the power line PL to the plurality of first light emitting diodes 120 and the plurality of second light emitting diodes 130. The plurality of second reflective electrodes RE2 can be electrically connected to the power line PL through a contact hole formed in the organic insulating layer 115. The plurality of second reflective electrodes RE2 can be electrically connected to a common electrode CE through a contact hole of the first planarization layer 116 and the second planarization layer 117. Accordingly, a first n-type electrode 124 and a first n-type semiconductor layer 121 of the first light emitting diode 120 and a second n-type electrode 134 and a second n-type semiconductor layer 131 of the second light emitting diode 130 can be electrically connected to the power line PL through the plurality of second reflective electrodes RE2 and the common electrode CE.

In the meantime, the plurality of 1-1-th reflective electrodes RE1a, the plurality of 1-2-th reflective electrodes RE1b, and the plurality of second reflective electrodes RE2 may not overlap the second light emitting diode 130 so as to allow the light emitted from the second light emitting diode 130 to travel toward the bottom of the substrate 110. In this case, the second sub pixel SP2 can be formed by an emission area which overlaps the second light emitting diode 130 so that light emitted from the second light emitting diode 130 is emitted and a non-emission area which overlaps the 1-2-th reflective electrode RE1b and the second reflective electrode RE2 so that the light is not emitted.

In each of the plurality of first sub pixels SP1, the first light emitting diode 120 is disposed on the 1-1-th reflective electrode RE1a. The plurality of first light emitting diodes 120 is elements which emit light by a current and can include light emitting diodes which emit red light, green light, and blue light and implement various colored light including white by a combination thereof. For example, the plurality of first light emitting diodes 120 can be light emitting diodes (LED) or micro LEDs, but is not limited thereto.

The plurality of first light emitting diodes 120 is light emitting diodes which display images to a user who views the display panel PN on the front surface of the substrate 110. Light emitted from the plurality of first light emitting diodes 120 can travel toward the top of the substrate 110. At least a part of light emitted from the plurality of first light emitting diodes 120 is reflected by the plurality of first reflective electrodes RE1 and the plurality of second reflective electrodes RE2 to travel toward the top of the substrate 110.

Each of the plurality of first light emitting diodes 120 includes a first n-type semiconductor layer 121, a first emission layer 122, a first p-type semiconductor layer 123, a first n-type electrode 124, a first p-type electrode 125, and a first encapsulation film 126.

The first p-type semiconductor layer 123 is disposed on the 1-1-th reflective electrode RE1a and the first n-type semiconductor layer 121 is disposed on the first p-type semiconductor layer 123. Each of the first p-type semiconductor layer 123 and the first n-type semiconductor layer 121 can be formed by doping p-type and n-type impurities into a specific material. For example, each of the first p-type semiconductor layer 123 and the first n-type semiconductor layer 121 can be a layer doped with p-type and n-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium (Ge), tin (Sn), and the like, but are not limited thereto.

The first emission layer 122 is disposed between the first p-type semiconductor layer 123 and the first n-type semiconductor layer 121. The first emission layer 122 is supplied with holes and electrons from the first p-type semiconductor layer 123 and the first n-type semiconductor layer 121 to emit light. The first emission layer 122 can be formed by a single layer or a multi-quantum well (MQW) structure, and for example, can be formed of indium gallium nitride (InGaN) or gallium nitride (GaN), but is not limited thereto.

The first p-type electrode 125 is disposed below the first p-type semiconductor layer 123. The first p-type electrode 125 can be disposed on the bottom surface of the first p-type semiconductor layer 123. The first p-type electrode 125 is an electrode for electrically connecting the first light emitting diode 120, and the 1-1-th reflective electrode RE1a and the driving transistor DT. The first p-type electrode 125 is in contact with the 1-1-th reflective electrode RE1a to be electrically connected to the 1-1-th reflective electrode RE1a. The first p-type electrode 125 can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The first n-type electrode 124 is disposed on the first n-type semiconductor layer 121. The first n-type electrode 124 is an electrode which electrically connects the common electrode CE and the first n-type semiconductor layer 121. The first n-type electrode 124 can be formed of the transparent conductive material to allow the light emitted from the first emission layer 122 to be directed to the top of the substrate 110, for example, the top of the first light emitting diode 120. For example, the first n-type electrode 124 can be formed of a transparent conductive material, such as indium tin oxide (ITO) or indium zinc oxide (IZO), but is not limited thereto.

The first encapsulation film 126 is disposed so as to enclose at least a part of the first p-type semiconductor layer 123, the first emission layer 122, and the first n-type semiconductor layer 121. The first encapsulation film 126 is formed of an insulating material to protect the first p-type semiconductor layer 123, the first emission layer 122, and the first n-type semiconductor layer 121. The first encapsulation film 126 can cover a side surface of the first p-type semiconductor layer 123, a side surface of the first emission layer 122, and a side surface of the first n-type semiconductor layer 121. The first n-type electrode 124 and the first p-type electrode 125 are exposed from the first encapsulation film 126 to electrically connect the first n-type electrode 124 and the common electrode CE and electrically connect the first p-type electrode 125 to the 1-1-th reflective electrode RE1a and the driving transistor DT. The first encapsulation film 126 can be formed of any one of insulating materials, such as silicon oxide (Siox) or silicon nitride (SiNx), but is not limited thereto.

A first black matrix BM1 is disposed between the plurality of first light emitting diodes 120 on the organic insulating layer 115. The first black matrix BM1 can be disposed so as to enclose the circumference of the first light emitting diode 120 of the plurality of first sub pixels SP1. The first black matrix BM1 shields some light which is directed to an adjacent first sub pixel SP1, among light emitted from the first light emitting diode 120, to suppress the color mixture of the light emitted from each of the plurality of first sub pixels SP1. The first black matrix BM1 can guide light emitted from the first light emitting diode 120 to be emitted toward the top of the substrate 110 so as to correspond to only an area of the first sub pixel SP1 in which the first light emitting diode 120 is disposed. The first black matrix BM1 shields some light which is directed to the adjacent second sub pixel SP2, among light emitted from the first light emitting diode 120, together with the second black matrix BM2, to suppress the color mixture of light of the plurality of first sub pixels SP1 and light of the plurality of second sub pixels SP2.

A first planarization layer 116 and a second planarization layer 117 are disposed on the plurality of first light emitting diodes 120. The first planarization layer 116 is disposed on the plurality of first reflective electrodes RE1, the plurality of second reflective electrodes RE2, and the plurality of first light emitting diodes 120 and the second planarization layer 117 is disposed on the first planarization layer 116. The first planarization layer 116 and the second planarization layer 117 are disposed to fill a space between the first black matrixes BM1 to fix and protect the plurality of first light emitting diodes 120. The first planarization layer 116 and the second planarization layer 117 can be configured by a single layer or a double layer, and for example, can be formed of photoresist or an acrylic organic material, but is not limited thereto.

The common electrode CE is disposed on the entire surface of the substrate 110 on the second planarization layer 117. The common electrodes CE is an electrode which electrically connects the power line PL to the plurality of first light emitting diodes 120 and the plurality of second light emitting diodes 130. The common electrode CE can be electrically connected to the plurality of second reflective electrodes RE2 through a contact hole of the first planarization layer 116 and the second planarization layer 117. Therefore, the common electrode CE can be electrically connected to the power line PL through the plurality of second reflective electrodes RE2. The common electrode CE can be electrically connected to the first n-type electrode 124 of the plurality of first light emitting diodes 120 through a contact hole of the second planarization layer 117. Finally, the common electrode CE is in contact with the second n-type electrode 134 of the second light emitting diode 130 to be electrically connected.

The common electrode CE is formed of a transparent conductive material to allow light emitted from the first light emitting diode 120 and light emitted from the second light emitting diode 130 to pass through. Light emitted from the first light emitting diode 120 below the common electrode CE transmits the common electrode CE to travel toward the top of the substrate 110. Light emitted from the second light emitting diode 130 transmits the common electrode CE to travel toward the bottom of the substrate 110. For example, the common electrode CE can be formed of a transparent conductive material, such as indium tin oxide (ITO) or indium zinc oxide (IZO), but is not limited thereto.

The common electrode CE includes a plurality of openings CEO. The plurality of openings CEO of the common electrode CE is disposed so as to overlap the plurality of second sub pixels SP2. The common electrode CE can include an opening CEO which is partially open to connect a third reflective electrode RE3 disposed above the common electrode CE and the second reflective electrode RE2 disposed below the common electrode CE. In an area corresponding to the plurality of openings CEO, a contact hole through which the third reflective electrode RE3 and the second reflective electrode RE2 above and below the common electrode CE are electrically connected can be formed.

In each of the plurality of second sub pixels SP2, the second light emitting diode 130 is disposed on the common electrode CE. The plurality of second light emitting diodes 130 is elements which emit light by a current and can include light emitting diodes which emit red light, green light, and blue light and implement various colored light including white by a combination thereof. For example, the plurality of second light emitting diodes 130 can be light emitting diodes (LED) or micro LEDs, but is not limited thereto.

The plurality of second light emitting diodes 130 are light emitting diodes which display images to a user who views the display panel PN on the rear surface of the substrate 110. Light emitted from the plurality of second light emitting diodes 130 can travel toward the bottom of the substrate 110. Light emitted from the plurality of second light emitting diodes 130 can be reflected from the plurality of third reflective electrodes RE3 to travel toward the bottom of the substrate 110.

Each of the plurality of second light emitting diodes 130 includes a second n-type semiconductor layer 131, a second emission layer 132, a second p-type semiconductor layer 133, a second n-type electrode 134, a second p-type electrode 135, and a second encapsulation film 136.

The second n-type semiconductor layer 131 is disposed on the common electrode CE and the second p-type semiconductor layer 133 is disposed on the second n-type semiconductor layer 131. Each of the second p-type semiconductor layer 133 and the second n-type semiconductor layer 131 can be formed by doping p-type and n-type impurities into a specific material. For example, each of the second p-type semiconductor layer 133 and the second n-type semiconductor layer 131 can be a layer doped with p-type and n-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium (Ge), tin (Sn), and the like, but are not limited thereto.

The second emission layer 132 is disposed between the second p-type semiconductor layer 133 and the second n-type semiconductor layer 131. The second emission layer 132 is supplied with holes and electrons from the second p-type conductive layer and the second n-type semiconductor layer 131 to emit light. The second emission layer 132 can be formed by a single layer or a multi-quantum well (MQW) structure, and for example, can be formed of indium gallium nitride (InGaN) or gallium nitride (GaN), but is not limited thereto.

The second n-type electrode 134 is disposed below the second n-type semiconductor layer 131. The second n-type electrode 134 can be disposed on the bottom surface of the second n-type semiconductor layer 131. The second n-type electrode 134 is an electrode which electrically connects the second light emitting diode 130 and the common electrode CE. The second n-type electrode 134 is in contact with the common electrode CE to be electrically connected to the common electrode CE. The second n-type electrode 134 can be formed of the transparent conductive material to allow the light emitted from the second emission layer 132 to be directed toward the bottom of the substrate 110, for example, the bottom of the second light emitting diode 130. For example, the second n-type electrode 134 can be formed of a transparent conductive material, such as indium tin oxide (ITO) or indium zinc oxide (IZO), but is not limited thereto.

The second p-type electrode 135 is disposed on the second p-type semiconductor layer 133. The second p-type electrode 135 is an electrode which electrically connects the second light emitting diode 130 to the driving transistor DT together with the third reflective electrode RE3 and the first reflective electrode RE1. The second p-type electrode 135 can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The second encapsulation film 136 is disposed so as to enclose at least a part of the second p-type semiconductor layer 133, the second emission layer 132, and the second n-type semiconductor layer 131. The second encapsulation film 136 is formed of an insulating material to protect the second p-type semiconductor layer 133, the second emission layer 132, and the second n-type semiconductor layer 131. The second encapsulation film 136 can cover a side surface of the second p-type semiconductor layer 133, a side surface of the second emission layer 132, and a side surface of the second n-type semiconductor layer 131. The second n-type electrode 134 and the second p-type electrode 135 are exposed from the second encapsulation film 136 to electrically connect the second n-type electrode 134 and the common electrode CE and electrically connect the second p-type electrode 135 to the third reflective electrode RE3 and the 1-2-th reflective electrode RE1b. The second encapsulation film 136 can be formed of any one of insulating materials, such as silicon oxide (Siox) or silicon nitride (SiNx), but is not limited thereto.

The second black matrix BM2 is disposed between the plurality of second light emitting diodes 130 on the common electrode CE and the second planarization layer 117. The second black matrix BM2 can be disposed so as to enclose the circumference of the second light emitting diode 130 of the plurality of second sub pixels SP2. The second black matrix BM2 shields some light which is directed to an adjacent second sub pixel SP2, among light emitted from the second light emitting diode 130, to suppress the color mixture of the light emitted from each of the plurality of second sub pixels SP2. The second black matrix BM2 can guide light emitted from the second light emitting diode 130 to be emitted toward the bottom of the substrate 110 so as to correspond to only an area of the second sub pixel SP2 in which the second light emitting diode 130 is disposed. The second black matrix BM2 shields some light which is directed to the adjacent first sub pixel SP1, among light emitted from the second light emitting diode 130 together with the first black matrix BM1, to suppress the color mixture of light of the plurality of first sub pixels SP1 and light of the plurality of second sub pixels SP2.

At this time, the first black matrix BM1 and the second black matrix BM2 can be alternately disposed in the plan view. The plurality of first light emitting didoes 120 and the plurality of second light emitting diodes 130 are alternately disposed and the first black matrix BM1 and the second black matrix BM2 which enclose the plurality of first light emitting didoes 120 and the plurality 4 second light emitting diodes 130 can also be alternately disposed.

A third planarization layer 118 and a fourth planarization layer 119 are disposed on the plurality of second light emitting diodes 130. The third planarization layer 118 is disposed on the common electrode CE and the plurality of second light emitting diodes 130 and the fourth planarization layer 119 is disposed on the third planarization layer 118. The third planarization layer 118 and the fourth planarization layer 119 are disposed to fill a space between the second black matrixes BM2 to fix and protect the plurality of second light emitting diodes 130. The third planarization layer 118 and the fourth planarization layer 119 can be configured by a single layer or a double layer, and for example, can be formed of photoresist or an acrylic organic material, but is not limited thereto.

In each of the plurality of second sub pixels SP2, the plurality of third reflective electrodes RE3 is disposed on the fourth planarization layer 119. The plurality of third reflective electrodes RE3 can electrically connect the second light emitting diode 130, and the 1-2-th reflective electrodes RE1b and the driving transistor DT and also serve as a reflective plate which reflects light emitted from the second light emitting diode 130. The plurality of third reflective electrodes RE3 is disposed in the plurality of second sub pixels SP2 to reflect light emitted from the second light emitting diode 130 toward the bottom of the substrate 110 which is the bottom of the second light emitting diode 130. At this time, the plurality of third reflective electrodes RE3 can be disposed to be spaced apart from the first sub pixel SP1 to allow the light emitted from the first light emitting diode 120 to travel toward the top of the substrate 110. The third reflective electrode RE3 can be disposed so as not to overlap the first sub pixel SP1 and so as to overlap the second sub pixel SP2. The plurality of third reflective electrodes RE3 is formed of a conductive material having excellent reflective property to reflect light emitted from a second light emitting diode 130, among the plurality of light emitting diodes 120 and 130, toward the bottom of the second light emitting diode 130. For example, the plurality of third reflective electrodes RE3 can be formed of a metal material having an excellent reflective property, such as aluminum (Al), silver (Ag), copper (Cu), palladium (Pd), or an alloy thereof, but is not limited thereto.

Each of the plurality of third reflective electrodes RE3 can be electrically connected to the second p-type electrode 135 of the second light emitting diode 130 through a contact hole of the fourth planarization layer 119. Each of the plurality of third reflective electrodes RE3 can be electrically connected to the 1-2-th reflective electrode RE1b through a contact hole formed in the fourth planarization layer 119, the third planarization layer 118, the second planarization layer 117, and the first planarization layer 116 in an area corresponding to the opening CEO of the common electrode CE. Therefore, the second p-type electrode 135 of the second light emitting diode 130 can be electrically connected to the driving transistor DT through the third reflective electrode RE3 and the 1-2-th reflective electrode RE1b.

Accordingly, the display device 100 according to the example embodiment of the present disclosure includes the plurality of first sub pixels SP1 which emits light to the front surface of the substrate 110 and the plurality of second sub pixels SP2 which emits light to the rear surface of the substrate 110 to serve as a dual emission display device 100 which displays images on both surfaces. In the plurality of first sub pixels SP1, the first light emitting diode 120 is disposed on the 1-1-th reflective electrode RE1a and the second reflective electrode RE2 to allow the light emitted from the first light emitting diode 120 to travel toward the top of the substrate 110. In the plurality of second sub pixels SP2, the second light emitting diode 130 is disposed below the third reflective electrode RE3 to allow the light emitted from the second light emitting diode 130 to travel toward the bottom of the substrate 110. At this time, the first light emitting diode 120 is disposed so as not to overlap the third reflective electrode RE3 formed above the first light emitting diode 120 and the second light emitting diode 130 is disposed so as not to overlap the first reflective electrode RE1 and the second reflective electrode RE2 formed below the second light emitting diode 130. Therefore, the light emitted from the first light emitting diode 120 and the second light emitting diode 130 can easily travel toward the top and the bottom of the substrate 110, respectively. Accordingly, the display device 100 according to the example embodiment of the present disclosure includes the plurality of first sub pixels SP1 and the plurality of second sub pixels SP2 which emit light to different directions to display images on both surfaces of the substrate 110.

In the display device 100 according to the example embodiment of the present disclosure, the plurality of first light emitting diodes 120 and the plurality of second light emitting diodes 130 are alternately disposed in the plan view. Further, the black matrixes which enclose each of the plurality of first light emitting diodes 120 and the plurality of second light emitting diodes 130 are formed. Therefore, interference of light and a crosstalk caused by the light interference can be reduced. The plurality of first light emitting diodes 120 and the plurality of second light emitting diodes 130 are disposed in different areas and may not overlap. Among light emitted from the plurality of first light emitting diodes 120, light which travels to the adjacent second sub pixel SP2 or light which travels toward the bottom of the substrate 110 can be blocked by the first black matrix BM1 and the second black matrix BM2. Among light emitted from the plurality of second light emitting diodes 130, light which travels to the adjacent first sub pixel SP1 or light which travels toward the top of the substrate 110 can be blocked by the first black matrix BM1 and the second black matrix BM2. Accordingly, on the front surface of the substrate 110, the image can be displayed only by light emitted from the first light emitting diode 120 and on the rear surface of the substrate 110, the image can be displayed only by light emitted from the second light emitting diode 130. Therefore, the crosstalk caused by the interference of light emitted from the first light emitting diode 120 and light emitted from the second light emitting diode 130 can be suppressed and the degradation of the display quality can also be suppressed.

In the display device 100 according to the example embodiment of the present disclosure, the first light emitting diode 120 and the second light emitting diode 130 are disposed in a vertically symmetrical structure to simplify the connection structure of the first light emitting diode 120 and the second light emitting diode 130, and the power line PL. Specifically, the first light emitting diode 120 can be driven by connecting the first p-type electrode 125 to the driving transistor DT and connecting the first n-type electrode 124 to the power line PL. The second light emitting diode 130 can be driven by connecting the second p-type electrode 135 to the driving transistor DT and connecting the second n-type electrode 134 to the power line PL. The first n-type electrode 124 of the first light emitting diode 120 and the second n-type electrode 134 of the second light emitting diode 130 are commonly connected to the power line PL to be applied with a power voltage. At this time, the first light emitting diode 120 can be aligned such that the first n-type electrode 124 is located at the top and the second light emitting diode 130 can be aligned such that the second n-type electrode 134 is located at the bottom. The common electrode CE is formed on a layer between the first light emitting diode 120 and the second light emitting diode 130 to electrically connect the first n-type electrode 124 of the first light emitting diode 120 and the second n-type electrode 134 of the second light emitting diode 130 to the common electrode CE. For example, the common electrode CE which is disposed above the first light emitting diode 120 can be electrically connected to the first n-type electrode 124 through a contact hole of the second planarization layer 117. The second n-type electrode 134 of the second light emitting diode 130 is in direct contact on the common electrode CE disposed below the second light emitting diode 130 to electrically connect the common electrode CE and the second n-type electrode 134. Therefore, the common electrode CE is formed on a layer between the first light emitting diode 120 and the second light emitting diode 130 and the first light emitting diode 120 and the second light emitting diode 130 are aligned such that each of the first n-type electrode 124 and the second n-type electrode 134 is directed to the common electrode CE. By doing this, the connection structure of the first light emitting diode 120, the second light emitting diode 130, and the common electrode CE can be simplified.

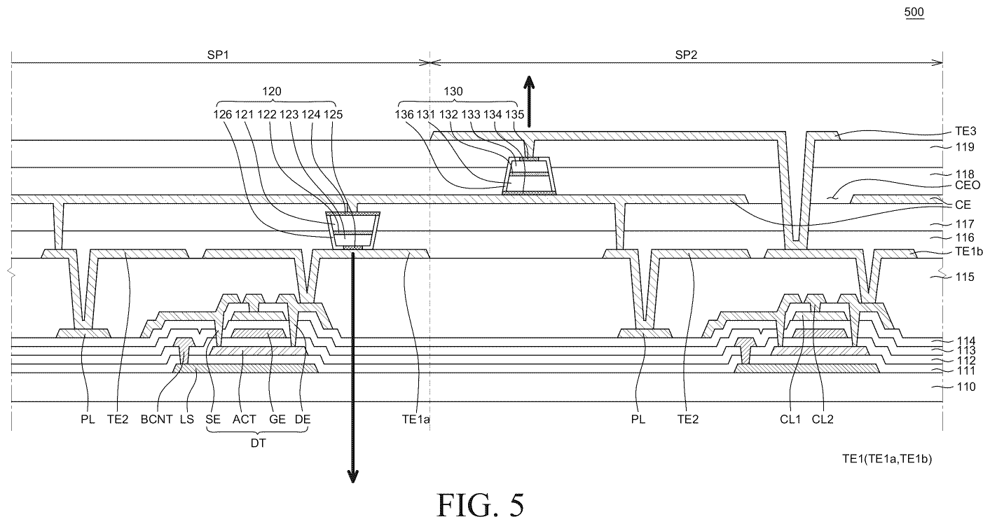

FIG. 5 is a cross-sectional view of a sub pixel of a display device according to another example embodiment of the present disclosure. A display device 500 of FIG. 5 is substantially the same as the display device 100 of FIGS. 1 to 4 except that a black matrix is not provided, a transmissive electrode is provided, instead of the reflective electrode, and a common electrode CE is different so that a redundant description will be omitted or may be briefly provided.

Referring to FIG. 5, the plurality of first sub pixels SP1 and the plurality of second sub pixels SP2 can display images on different surfaces of the substrate 110. For example, the plurality of first sub pixels SP1 emits light toward the bottom of the substrate 110 to display an image on the rear surface of the substrate 110 and the plurality of second sub pixels SP2 emits light toward the top of the substrate 110 to display an image on the front surface of the substrate 110.

Therefore, light emitted from the first light emitting diode 120 of the plurality of first sub pixels SP1 can be emitted toward the bottom of the substrate 110 and light emitted from the second light emitting diode 130 of the plurality of second sub pixels SP2 can be emitted toward the top of the substrate 110. In this case, the second light emitting diode 130 for displaying an image on the front surface of the substrate 110 can also be referred to as the top emission light emitting diode and the first light emitting diode 120 for displaying an image on the rear surface of the substrate 110 can also be referred to as the bottom emission light emitting diode.

In this case, the common electrode CE is formed of an opaque conductive material having an excellent reflective property to travel light emitted from the first light emitting diode 120 and the second light emitting diode 130 to the bottom of the substrate 110 and the top of the substrate 110, respectively. Specifically, the common electrode CE disposed above the first light emitting diode 120 can reflect light which is directed to the top of the substrate 110, among light emitted from the first light emitting diode 120, toward the bottom of the substrate 110. The common electrode CE disposed below the second light emitting diode 130 can reflect light which is directed to the bottom of the substrate 110, among light emitted from the second light emitting diode 130, toward the top of the substrate 110. For example, the common electrode CE can be formed of a metal material having an excellent reflective property, such as aluminum (Al), silver (Ag), copper (Cu), palladium (Pd), or an alloy thereof, but is not limited thereto.

In order to allow the light emitted from the first light emitting diode 120 to travel toward the bottom of the substrate 110 and light emitted from the second light emitting diode 130 to travel toward the top of the substrate 110, a plurality of transmissive electrodes can be disposed, instead of the plurality of reflective electrodes. The plurality of transmissive electrodes can be electrodes which electrically connect the first light emitting diode 120 and the second light emitting diode 130 to the driving transistor DT and the power line PL. The plurality of transmissive electrodes is formed of a transparent conductive material to transmit light emitted from the first light emitting diode 120 and the second light emitting diode 130 to be emitted to the bottom and the top of the substrate 110, respectively. For example, the plurality of transmissive electrodes is configured of a transparent conductive material, such as indium tin oxide (ITO) or indium zinc oxide (IZO), but is not limited thereto.

The plurality of transmissive electrodes includes a plurality of first transmissive electrodes TE1, a plurality of second transmissive electrodes TE2, and a plurality of third transmissive electrodes TE3. The plurality of first transmissive electrodes TE1 includes a plurality of 1-1-th transmissive electrodes TE1a and a plurality of 1-2-th transmissive electrodes TE1b.

First, the plurality of first transmissive electrodes TE1 are disposed in each of the plurality of sub pixels SP on the organic insulating layer 115. The plurality of first transmissive electrodes TE1 can electrically connect each of the first light emitting diode 120 and the second light emitting diode 130 to the driving transistor DT. The plurality of first transmissive electrodes TE1 can be connected to the source electrode SE or the drain electrode DE of the driving transistor DT through a contact hole formed in the organic insulating layer 115. The first transmissive electrode TE1 can be electrically connected to each of a first p-type electrode 125 of the first light emitting diode 120 and a second p-type electrode 135 of the second light emitting diode 130.

The plurality of first transmissive electrodes TE1 include a plurality of 1-1-th transmissive electrodes TE1a and a plurality of 1-2-th transmissive electrodes TE1b. The 1-1-th transmissive electrode TE1a can be disposed in the first sub pixel SP1 and the 1-2-th transmissive electrode TE1b can be disposed in the second sub pixel SP2. The plurality of 1-1-th transmissive electrodes TE1a is electrodes which electrically connect the plurality of first light emitting diodes 120 and the driving transistor DT in the first sub pixel SP1. Further, the plurality of 1-2-th transmissive electrodes TE1b is electrodes which electrically connect the plurality of second light emitting diodes 130 and the driving transistor DT in the second sub pixel SP2. The first p-type electrode 125 of the first light emitting diode 120 is in direct contact with the top surface of the plurality of 1-1-th transmissive electrodes TE1a to electrically connect the first light emitting diode 120 to the 1-1-th transmissive electrode TE1a. The 1-2-th transmissive electrode TE1b can be electrically connected to the second p-type electrode 135 of the second light emitting diode 130 through the third transmissive electrode TE3.

At this time, the first light emitting diode 120 which is in direct contact with the top surface of the 1-1-th transmissive electrode TE1a to be electrically connected to the 1-1-th transmissive electrode TE1a is disposed so as to overlap the 1-1-th transmissive electrode TE1a. In order to emit light emitted from the first light emitting diode 120 toward the bottom of the substrate 110, the 1-1-th transmissive electrode TE1a disposed below the first light emitting diode 120 can be formed of a transparent conductive material. Light emitted from the first light emitting diode 120 can transmit the 1-1-th transmissive electrode TE1a to be directed to the bottom of the substrate 110.

Additionally, in order to allow light emitted from the first light emitting diode 120 to travel toward the bottom of the substrate 110, the first light emitting diode 120 can be disposed so as not to overlap the driving transistor DT or the power line PL disposed in the first sub pixel SP1.

Next, the plurality of second transmissive electrodes TE2 is disposed in each of the plurality of sub pixels SP on the organic insulating layer 115. The plurality of second transmissive electrodes TE2 can electrically connect the power line PL to the plurality of first light emitting diodes 120 and the plurality of second light emitting diodes 130 together with the common electrode CE. The plurality of second transmissive electrodes TE2 can be electrically connected to the power line PL through a contact hole formed in the organic insulating layer 115. The plurality of second transmissive electrodes TE2 can be electrically connected to a common electrode CE through a contact hole of the first planarization layer 116 and the second planarization layer 117. Accordingly, a first n-type electrode 124 and a first n-type semiconductor layer 121 of the first light emitting diode 120 and a second n-type electrode 134 and a second n-type semiconductor layer 131 of the second light emitting diode 130 can be electrically connected to the power line PL through the plurality of second transmissive electrodes TE2 and the common electrode CE.

Next, the third transmissive electrode TE3 is disposed in each of the plurality of second sub pixels SP2 on the fourth planarization layer 119. The second transmissive electrode TE3 is an electrode which electrically connects the second light emitting diode 130 to the driving transistor DT together with the 1-2-the transmissive electrode TE1b. The third transmissive electrode TE3 can be electrically connected to the 1-2-th transmissive electrode TE1b through a contact hole overlapping the opening CEO of the common electrode CE. Therefore, the third transmissive electrode TE3 can be electrically connected to the driving transistor DT through the 1-2-th transmissive electrode TE1b. The third transmissive electrode TE3 can be electrically connected to the second p-type electrode 135 of the second light emitting diode 130 through a contact hole of the fourth planarization layer 119. The third transmissive electrode TE3 is disposed to overlap the second light emitting diode 130, but is formed of a transparent conductive material so that light from the second light emitting diode 130 transmits the third transmissive electrode TE3 to travel toward the top of the substrate 110.

Accordingly, in the display device 500 according to another example embodiment of the present disclosure, the common electrode CE disposed above the first light emitting diode 120 and below the second light emitting diode 130 is formed of an opaque conductive material. Therefore, the first light emitting diode 120 is driven to display the image on the rear surface of the substrate 110 and the second light emitting diode 130 is driven to display the image on the front surface of the substrate 110. The common electrode CE which is formed of an opaque conductive material is disposed on the entire surface of the substrate 110, on the layer between the first light emitting diode 120 and the second light emitting diode 130. Therefore, light emitted from the first light emitting diode 120 can be emitted only toward the bottom of the substrate 110 and light emitted from the second light emitting diode 130 can be emitted only toward the top of the substrate 110. By doing this, the dual emission display device 500 which displays images on both surfaces can be implemented by placing the first light emitting diode 120 and the second light emitting diode 130 below and above the opaque common electrode CE, respectively.

Further, in the display device 500 according to another example embodiment of the present disclosure, the common electrode CE formed of an opaque conductive material is formed on the entire surface of the substrate 110 on the layer between the first light emitting diode 120 and the second light emitting diode 130. Light of the first light emitting diode 120 and light of the second light emitting diode 130 may not interfere with each other. Light emitted from the first light emitting diode 120 cannot travel to the top of the substrate 110 by the common electrode CE and light emitted from the second light emitting diode 130 cannot travel to the bottom of the substrate 110 by the common electrode CE. Therefore, light from the first light emitting diode 120 and light from the second light emitting diode 130 may not interfere with each other by the common electrode CE and the crosstalk due to the light interference may not be generated. In this case, the first black matrix BM1 which encloses the first light emitting diode 120 and the second black matrix BM2 which encloses the second light emitting diode 130 can be omitted. Even though the first black matrix BM1 and the second black matrix BM2 are not disposed, light of the first light emitting diode 120 which is directed toward the top of the substrate 110 can be shielded and light of the second light emitting diode 130 which is directed toward the bottom of the substrate 110 can be shielded by the common electrode CE. Therefore, the first black matrix BM1 and the second black matrix BM2 are omitted to simplify the structure of the display device 500.

The example embodiments of the present disclosure can also be described as follows:

According to an aspect of the present disclosure, a display device includes a substrate including a plurality of first sub pixels and a plurality of second sub pixels, a plurality of first light emitting diodes which is disposed in the plurality of first sub pixels and emits light to one surface of the substrate, and a plurality of second light emitting diodes which is disposed in the plurality of second sub pixels and emits light to an opposite surface to the one surface of the substrate. The plurality of first light emitting diodes and the plurality of second light emitting diodes are alternately disposed in a plan view.

The display device can further include a plurality of 1-1-th reflective electrodes which is disposed between the substrate and the plurality of first light emitting diodes in the plurality of first sub pixels, a plurality of 1-2-th reflective electrodes which is disposed between the substrate and the plurality of second light emitting diodes in the plurality of second sub pixels, a plurality of second reflective electrodes which is disposed on the same layer as the plurality of 1-1-th reflective electrodes and the plurality of 1-2-th reflective electrodes in the plurality of first sub pixels and the plurality of second sub pixels, and a plurality of third reflective electrodes which is disposed on the plurality of second light emitting diodes in the plurality of second sub pixels.

The plurality of first light emitting diodes can overlap the plurality of 1-1-th reflective electrodes and the plurality of second light emitting diodes may not overlap the plurality of 1-2-th reflective electrodes.

The plurality of second light emitting diodes can overlap the plurality of third reflective electrodes and may not overlap the plurality of second reflective electrodes.

Light emitted from the plurality of first light emitting diodes can be reflected to a top of the substrate by the plurality of 1-1-th reflective electrodes and the plurality of second reflective electrodes and light emitted from the plurality of second light emitting diodes can be reflected to a bottom of the substrate by the plurality of third reflective electrodes.

The display device can further include a first black matrix which is disposed in the plurality of first sub pixels and encloses each of the plurality of first light emitting diodes, and a second black matrix which is disposed in the plurality of second sub pixels and encloses each of the plurality of second light emitting diodes. Among light emitted from the plurality of first light emitting diodes, light directed to the plurality of adjacent second sub pixels can be shielded by the first black matrix and the second black matrix and among light emitted from the plurality of second light emitting diodes, light directed to the plurality of adjacent first sub pixels can be shielded by the first black matrix and the second black matrix.

The display device can further include a first planarization layer which is disposed on the plurality of 1-1-th reflective electrodes, the plurality of 1-2-th reflective electrodes, and the plurality of second reflective electrodes and encloses the plurality of first light emitting diodes, a second planarization layer disposed on the first planarization layer, a common electrode which is disposed on the second planarization layer and includes a plurality of openings disposed in the plurality of second sub pixels, a third planarization layer which is disposed on the common electrode and encloses the plurality of second light emitting diodes, and a fourth planarization layer disposed between the third planarization layer and the plurality of third reflective electrodes.

The plurality of third reflective electrodes and the plurality of 1-2-th reflective electrodes can be electrically connected to each other through a contact hole formed in the fourth planarization layer, the third planarization layer, the second planarization layer, and the first planarization layer and the contact hole can overlap the plurality of openings of the common electrode.

The common electrode can be formed of a transparent conductive material and light emitted from the plurality of first light emitting diodes can pass through the common electrode to travel to a top of the substrate and light emitted from the plurality of second light emitting diodes can pass through the common electrode to travel to a bottom of the substrate.

The display device can further include a plurality of 1-1-th transmissive electrodes which is disposed between the substrate and the plurality of first light emitting diodes in the plurality of first sub pixels, a plurality of 1-2-th transmissive electrodes which is disposed between the substrate and the plurality of second light emitting diodes in the plurality of second sub pixels, a plurality of second transmissive electrodes which is disposed on the same layer as the plurality of 1-1-th transmissive electrodes and the plurality of 1-2-th transmissive electrodes in the plurality of first sub pixels and the plurality of second sub pixels, and a plurality of third transmissive electrodes which is disposed on the plurality of second light emitting diodes in the plurality of second sub pixels.

The plurality of first light emitting diodes can overlap the plurality of 1-1-th transmissive electrodes and the plurality of second light emitting diodes can overlap the plurality of third transmissive electrodes and light emitted from the plurality of first light emitting diodes passes through the plurality of 1-1-th transmissive electrodes to travel to a bottom of the substrate and light emitted from the plurality of second light emitting diodes passes through the plurality of third transmissive electrodes to travel to a top of the substrate.

The display device can further include a common electrode which is disposed on an entire surface of the substrate between the plurality of first light emitting diodes and the plurality of second light emitting diodes, and the common electrode can be formed of an opaque conductive material.

Light emitted from the plurality of first light emitting diodes can be reflected by the common electrode to a bottom of the substrate and light emitted from the plurality of second light emitting diodes can be reflected by the common electrode to a top of the substrate.

Each of the plurality of first light emitting diodes can include a first emission layer, a first n-type electrode disposed on the first emission layer, and a first p-type electrode disposed below the first emission layer, and each of the plurality of second light emitting diodes can include a second emission layer, a second n-type electrode disposed below the second emission layer, and a second p-type electrode disposed on the second emission layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of first sub pixels and a plurality of second sub pixels;
a plurality of first light emitting diodes disposed in the plurality of first sub pixels and configured to emit light to one surface of the substrate; and
a plurality of second light emitting diodes disposed in the plurality of second sub pixels and configured to emit light to another surface of the substrate being opposite to the one surface of the substrate,
wherein the plurality of first light emitting diodes and the plurality of second light emitting diodes are alternately disposed in a plan view.

2. The display device according to claim 1, further comprising:
a plurality of 1-1-th reflective electrodes disposed between the substrate and the plurality of first light emitting diodes in the plurality of first sub pixels;
a plurality of 1-2-th reflective electrodes disposed between the substrate and the plurality of second light emitting diodes in the plurality of second sub pixels;
a plurality of second reflective electrodes disposed on a same layer as the plurality of 1-1-th reflective electrodes and the plurality of 1-2-th reflective electrodes in the plurality of first sub pixels and the plurality of second sub pixels; and
a plurality of third reflective electrodes disposed on the plurality of second light emitting diodes in the plurality of second sub pixels.

3. The display device according to claim 2, wherein the plurality of first light emitting diodes overlaps the plurality of 1-1-th reflective electrodes, and the plurality of second light emitting diodes does not overlap the plurality of 1-2-th reflective electrodes.

4. The display device according to claim 2, wherein the plurality of second light emitting diodes overlaps the plurality of third reflective electrodes and does not overlap the plurality of second reflective electrodes.

5. The display device according to claim 4, wherein light emitted from the plurality of first light emitting diodes is reflected to a top of the substrate by the plurality of 1-1-th reflective electrodes and the plurality of second reflective electrodes, and
wherein light emitted from the plurality of second light emitting diodes is reflected to a bottom of the substrate by the plurality of third reflective electrodes.

6. The display device according to claim 4, further comprising:
a first black matrix disposed in the plurality of first sub pixels and enclosing each of the plurality of first light emitting diodes; and
a second black matrix disposed in the plurality of second sub pixels and enclosing each of the plurality of second light emitting diodes,
wherein among light emitted from the plurality of first light emitting diodes, light directed to the plurality of adjacent second sub pixels is shielded by the first black matrix and the second black matrix, and
wherein among light emitted from the plurality of second light emitting diodes, light directed to the plurality of adjacent first sub pixels is shielded by the first black matrix and the second black matrix.

7. The display device according to claim 4, further comprising:
a first planarization layer disposed on the plurality of 1-1-th reflective electrodes, the plurality of 1-2-th reflective electrodes, and the plurality of second reflective electrodes, and enclosing the plurality of first light emitting diodes;
a second planarization layer disposed on the first planarization layer;
a common electrode disposed on the second planarization layer and including a plurality of openings disposed in the plurality of second sub pixels;
a third planarization layer disposed on the common electrode and enclosing the plurality of second light emitting diodes; and
a fourth planarization layer disposed between the third planarization layer and the plurality of third reflective electrodes.

8. The display device according to claim 7, wherein the plurality of third reflective electrodes and the plurality of 1-2-th reflective electrodes are electrically connected to each other through a contact hole formed in the fourth planarization layer, the third planarization layer, the second planarization layer, and the first planarization layer, and
wherein the contact hole overlaps the plurality of openings of the common electrode.

9. The display device according to claim 7, wherein the common electrode includes a transparent conductive material,
wherein light emitted from the plurality of first light emitting diodes passes through the common electrode to travel to a top of the substrate, and
wherein light emitted from the plurality of second light emitting diodes passes through the common electrode to travel to a bottom of the substrate.

10. The display device according to claim 1, further comprising:
a plurality of 1-1-th transmissive electrodes disposed between the substrate and the plurality of first light emitting diodes in the plurality of first sub pixels;
a plurality of 1-2-th transmissive electrodes disposed between the substrate and the plurality of second light emitting diodes in the plurality of second sub pixels;
a plurality of second transmissive electrodes disposed on a same layer as the plurality of 1-1-th transmissive electrodes and the plurality of 1-2-th transmissive electrodes in the plurality of first sub pixels and the plurality of second sub pixels; and
a plurality of third transmissive electrodes disposed on the plurality of second light emitting diodes in the plurality of second sub pixels.

11. The display device according to claim 10, wherein the plurality of first light emitting diodes overlaps the plurality of 1-1-th transmissive electrodes, and the plurality of second light emitting diodes overlaps the plurality of third transmissive electrodes, and
wherein light emitted from the plurality of first light emitting diodes passes through the plurality of 1-1-th transmissive electrodes to travel to a bottom of the substrate, and light emitted from the plurality of second light emitting diodes passes through the plurality of third transmissive electrodes to travel to a top of the substrate.

12. The display device according to claim 10, further comprising:
a common electrode disposed on an entire surface of the substrate between the plurality of first light emitting diodes and the plurality of second light emitting diodes,
wherein the common electrode includes an opaque conductive material.

13. The display device according to claim 12, wherein light emitted from the plurality of first light emitting diodes is reflected by the common electrode to a bottom of the substrate, and light emitted from the plurality of second light emitting diodes is reflected by the common electrode to a top of the substrate.

14. The display device according to claim 1, wherein each of the plurality of first light emitting diodes includes:
a first emission layer;
a first n-type electrode disposed on the first emission layer; and
a first p-type electrode disposed below the first emission layer, and
wherein each of the plurality of second light emitting diodes includes:
a second emission layer;
a second n-type electrode disposed below the second emission layer; and
a second p-type electrode disposed on the second emission layer.

15. The display device according to claim 1, further comprising:
a plurality of first pad electrodes connected to the plurality of first sub pixels and the plurality of second sub pixels and disposed on a front surface of a display panel;
a plurality of second pad electrodes disposed on a back surface of the display panel and connected to a driving component of the display device disposed on the back surface of the display panel; and
a side line disposed along a side surface of the display panel and electrically connecting the plurality of first pad electrodes and the plurality of second pad electrodes.
